(19) United States
(12) Patent Application Publication
(10) Pub. No.: US 2016/0020158 A1
(43) Pub. Date: Jan. 21, 2016

(54) Systems and Methods for Self Test Circuit Security

(71) Applicant: LSI Corporation, San Jose, CA (US)

(72) Inventors: Ramesh C. Tekumalla, Breinigsville (PA); John Tseng, Redwood City, CA (US); Parag Madhani, Allentown (PA)

(73) Assignee: LSI Corporation, San Jose, CA (US)

(21) Appl. No.: 14/337,158

(22) Filed: Jul. 21, 2014

(51) Int. Cl. H01L 21/66; G06F 17/50; H01L 23/31; H01L 21/56; H01L 23/00

(52) U.S. Cl. CPC H01L 22/34; H01L 22/32; H01L 21/56; H01L 24/09; H01L 23/3114; G06F 17/5045; H01L 2224/09515; H01L 2224/081; H01L 2924/1431; H01L 2924/1304

(57) ABSTRACT

The present inventions are related to systems and methods for circuit implementation, and more particularly to systems and methods for securing data in a circuit.

### FIELD OF THE INVENTION

Embodiments are related to systems and methods for circuit implementation, and more particularly to systems and methods for securing data in a circuit.

### BACKGROUND

Modern electronic circuitry often includes various types of test circuitry allowing for circuit verification during one or more test modes. For example, circuits may include scan circuitry comprising scan chains formed of multiple scan cells or other types of built in self test circuitry. After deployment of a device including electronic circuitry, information generated as part of operating the circuitry may be accessible to a hacker by triggering the one or more test modes in the electronic circuitry. Such a breach of security exposes sensitive information.

Hence, for at least the aforementioned reasons, there exists a need in the art for advanced systems and methods for circuit design.

### SUMMARY

Embodiments are related to systems and methods for circuit implementation, and more particularly to systems and methods for securing data in a circuit.

Various embodiments of the present invention provide semiconductor devices that include a wafer. An overall circuit is implemented on the wafer and includes: a first cell, a second cell, an internal only pad, an external pad, a gate circuit, a test circuit. The test circuit is coupled to an output of the second cell and an output of the gate circuit. The overall circuit is selectably operable in a test mode or a functional mode based upon data received via the external pad. A first input of the gate circuit is coupled to the internal only pad and a second input of the gate circuit is coupled to an output of the first cell. The gate circuit is configured such that: the output of the gate circuit follows the output of the first cell when the internal only pad is asserted at a first level and the test mode of the overall circuit is selected; and the output of the gate circuit is fixed regardless of the output of the first cell when the internal only pad is asserted at a second level and the test mode of the overall circuit is selected.

This summary provides only a general outline of some embodiments of the invention. The phrases “in one embodiment,” “according to one embodiment,” “various embodiments”, “one or more embodiments”, “particular embodiments” and the like generally mean the particular feature, structure, or characteristic following the phrase is included in at least one embodiment of the present invention, and may be included in more than one embodiment of the present invention. Importantly, such phases do not necessarily refer to the same embodiment. Many other embodiments of the invention will become more fully apparent from the following detailed description, the appended claims and the accompanying drawings.

### BRIEF DESCRIPTION OF THE FIGURES

A further understanding of the various embodiments of the present invention may be realized by reference to the figures which are described in remaining portions of the specification. In the figures, like reference numerals are used throughout several figures to refer to similar components. In some instances, a sub-label consisting of a lower case letter is associated with a reference numeral to denote one of multiple similar components. When reference is made to a reference numeral without specification to an existing sub-label, it is intended to refer to all such multiple similar components.

FIGS. 1a-1b shows a circuit test system including data security control in accordance with some embodiments of the present invention;

FIG. 1c shows an unsecured cell of the circuit under test in accordance with various embodiments of the present invention;

FIG. 1d shows a secured cell of the circuit under test in accordance with various embodiments of the present invention;

FIG. 2 is a flow diagram showing a method in accordance with one or more embodiments of the present invention for securing select portions of a circuit; and

FIG. 3 shows a circuit design system integrating circuit security in accordance with particular embodiments of the present invention.

### DETAILED DESCRIPTION OF SOME EMBODIMENTS

Embodiments are related to systems and methods for circuit implementation, and more particularly to systems and methods for securing data in a circuit.

Various embodiments of the present invention provide semiconductor devices that include a wafer. An overall circuit is implemented on the wafer and includes: a first cell, a second cell, an internal only pad, an external pad, a gate circuit, a test circuit. The test circuit is coupled to an output of the second cell and an output of the gate circuit. The overall circuit is selectably operable in a test mode or a functional mode based upon data received via the external pad. A first input of the gate circuit is coupled to the internal only pad and a second input of the gate circuit is coupled to an output of the first cell. The gate circuit is configured such that: the output of the gate circuit follows the output of the first cell when the internal only pad is asserted at a first level and the test mode of the overall circuit is selected; and the output of the gate circuit is fixed regardless of the output of the first cell when the internal only pad is asserted at a second level and the test mode of the overall circuit is selected. In some cases, the output of the gate circuit is also configured to follow the output of the first cell when the functional mode of the overall circuit is selected. In various instances of the aforementioned embodiments, the overall circuit includes at least one scan chain, the second cell is included in the scan chain, and the first cell is not incorporated in any of the at least one scan chain.

In some particular embodiments, the gate circuit includes: a NAND gate having a first input coupled to the internal only pad and a second input coupled to a test select output associated with the external pad, and providing a gate signal; and an AND gate having a first input coupled to the gate signal and a second input coupled to the output of the first cell, and providing the output of the gate circuit.

In various instances of the aforementioned embodiments, the device further includes a test system electrically coupled to the wafer. In such instances, the test system is operable to assert the internal only pad at the first level. In some cases the test system is further operable to assert the external pad such that the test mode of the overall circuit is selected.

In some instances of the aforementioned embodiments, the device further includes a chip package encapsulating the wafer and including a plurality of pins. In such instances, the external pad is bonded to one of the plurality of pins, and the internal only pad is inaccessible via the plurality of pins. In one or more instances of the aforementioned embodiments, the device further includes a chip package encapsulating the wafer. The external pad is bonded to a contact on the chip package such that the external pad is electrically accessible external to the chip package, and the internal only pad is tied to the second level internal to the chip package. In some cases, the internal only pad is electrically inaccessible external to the chip package.

Other embodiments of the present invention provide methods for deploying a semiconductor device. The methods include providing the semiconductor device having a wafer upon which an overall circuit is implemented. The overall circuit includes: a first cell, a second cell, an internal only pad, an external pad, a gate circuit, and a test circuit. The test circuit is coupled to an output of the second cell and an output of the gate circuit, and the overall circuit is selectably operable in a test mode or a functional mode based upon data received via the external pad. A first input of the gate circuit is coupled to the internal only pad and a second input of the gate circuit is coupled to an output of the first cell, and the gate circuit is configured such that: the output of the gate circuit follows the output of the first cell when the internal only pad is asserted at a first level and the test mode of the overall circuit is selected; and the output of the gate circuit is fixed regardless of the output of the first cell when the internal only pad is asserted at a second level and the test mode of the overall circuit is selected.

In some instances of the aforementioned embodiments, the methods further include: electrically connecting the wafer to a test system; tying the internal only pad at the first level; asserting the external pad by the test system to engage a test mode of the overall circuit; and verifying the wafer using the test system. In various instances of the aforementioned embodiments, the methods further include: tying the internal only pad at the second level; and encapsulating the wafer in a chip package such that the internal only pad is inaccessible external to the chip package. In some such instances, encapsulating the wafer in the chip package includes: bonding an external contact of the chip package to the external pad; and bonding the internal only pad to an internal power rail of the chip package. As such, the internal only pad is not controllable external to the chip package beyond a power source applied to the chip package. In one or more instances of the aforementioned embodiments, the overall circuit includes at least one scan chain, the second cell is included in the scan chain, and the first cell is not incorporated in any of the at least one scan chain.

Yet other embodiments of the present invention provide circuit design tools. The circuit design tools include a processor operable of receiving a representation of an overall circuit, wherein the overall circuit includes a first cell, a second cell, a third cell, an internal only pad, an external pad, a gate circuit, and a test circuit; and wherein the processor is communicably coupled to a computer readable medium including instructions executable by the processor to: receive an identification of the cell as a secured memory; disconnect the secured memory from a scan chain in the overall circuit; connect a scan output from the second cell upstream from the secured memory in the scan chain to a scan input of the third cell downstream from the secured memory in the scan chain; connect the gate circuit to the secured memory such that a first input of the gate circuit is coupled to the internal only pad and a second input of the gate circuit is coupled to an output of the secured memory, and wherein the gate circuit is configured such that: the output of the gate circuit follows the output of the secured memory when the internal only pad is asserted at a first level and the test mode of the overall circuit is selected; and the output of the gate circuit is fixed regardless of the output of the secured memory when the internal only pad is asserted at a second level and the test mode of the overall circuit is selected.

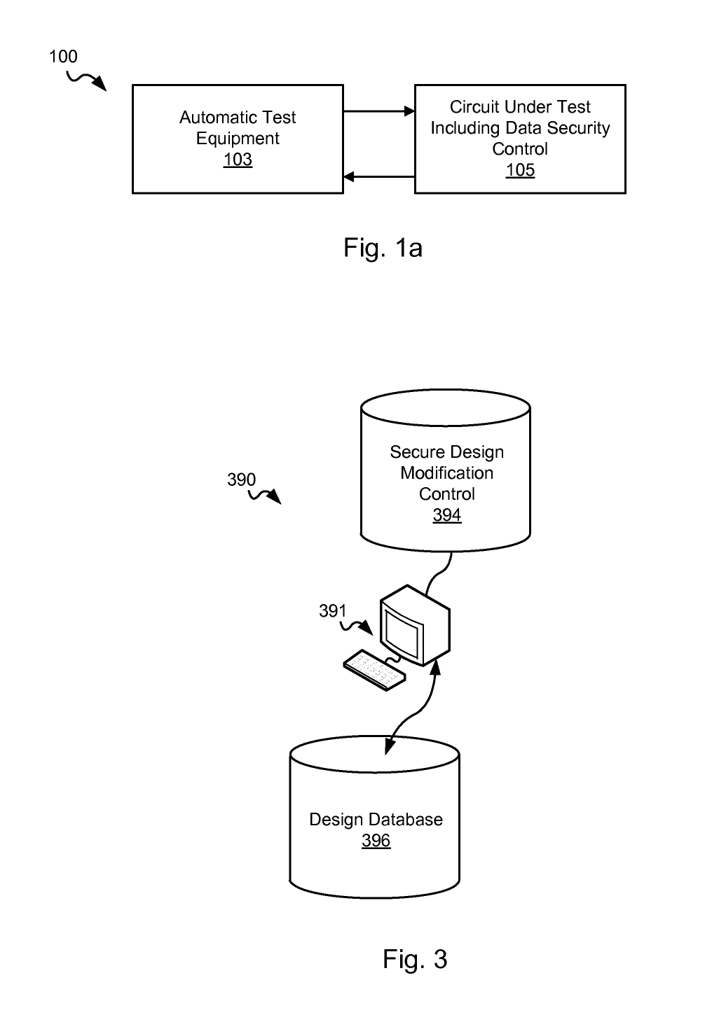

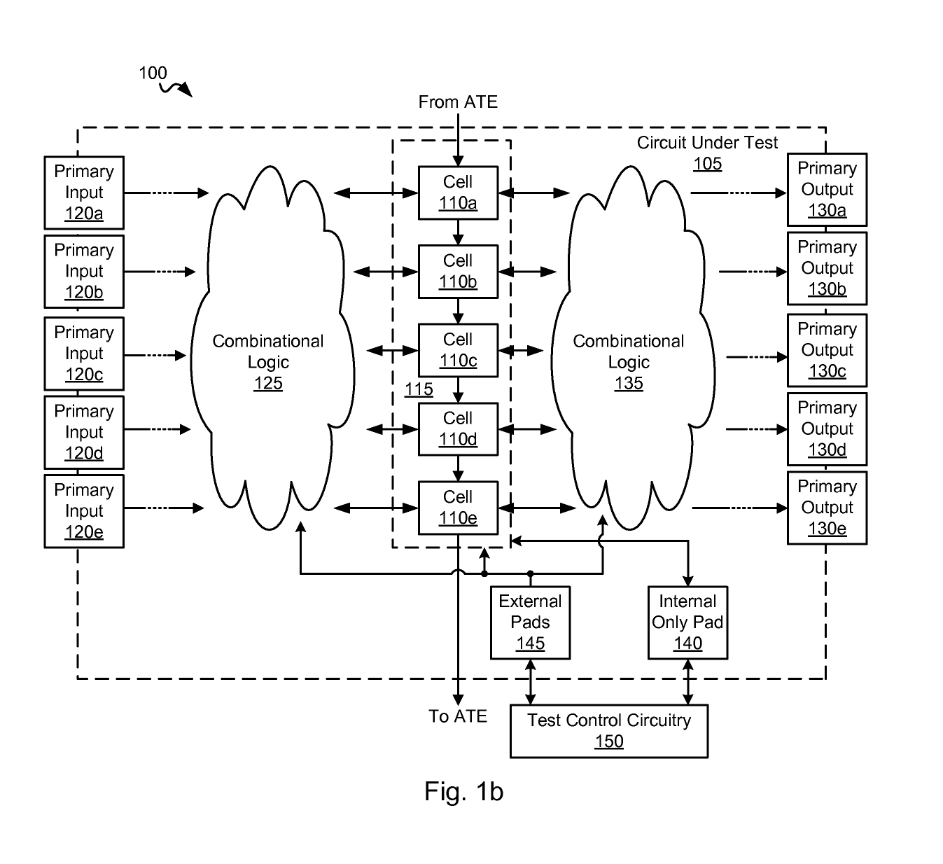

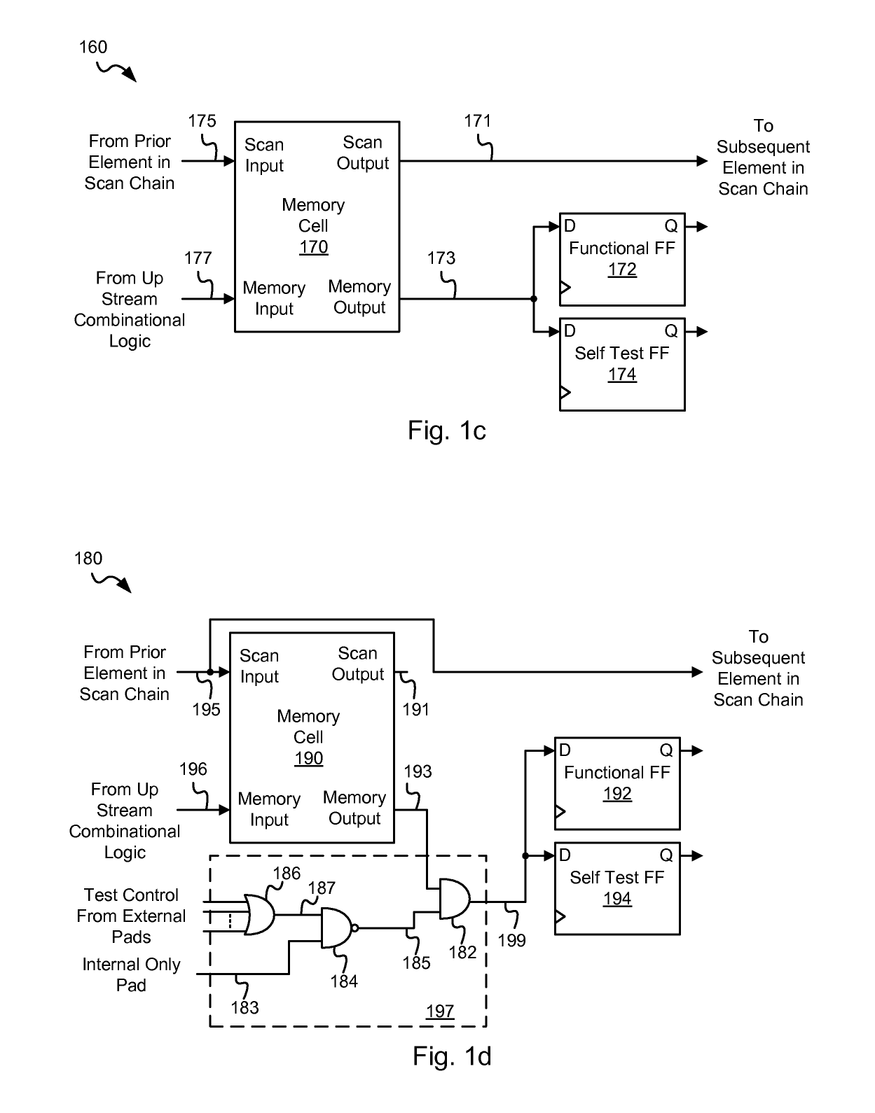

Turning to FIG. 1a, a circuit test system 100 including data security control is shown in accordance with some embodiments of the present invention. Circuit test system 100 includes automatic test equipment (ATE) 103 coupled to circuit under test 105. In operation, ATE 103 generates test patterns that are provided to circuit under test 105, and in turn receives outputs from circuit under test 105 that are stimulated by the test patterns. The test patterns may be generated by an automatic test pattern generator as are known in the art. ATE 103 then compares the received output with an expected output set to verify the proper functionality of circuit under test 105. ATE 103 may be any equipment or system know in the art for exercising circuit under test 105. As one example, ATE 103 may be a wafer test system that is operable to test circuit under test 105 prior to incorporating circuit under test 105 into a chip package. As another example, ATE 103 may be a chip test system operable to test circuit under test 105 after incorporating circuit under test 105 into a chip package. In some cases, all or part of ATE 103 may be implemented as an integrated circuit. In various cases, ATE 103 may be a software controlled test system. Based upon the disclosure provided herein, one of ordinary skill in the art will recognize a variety of ATE 103 that may be used to test circuit under test 105 in accordance with different embodiments of the present invention.

Circuit under test 105 may be any electronic circuit including a memory element that may be surreptitiously accessed. In some cases, circuit under test 105 is an integrated circuit including one or more scan chains or other built in self test circuitry. Circuit under test 105 may be an integrated circuit at different stages of manufacture including, but not limited to, a wafer stage (i.e., an integrated circuit prior to bonding to a chip package), or a chip stage (i.e., an integrated circuit after bonding to a chip package). Circuit under test 105 includes an internal only pad (shown as internal only pad 140 of FIG. 1b) that is used to disable access to a subset of test circuitry included in circuit under test 105. As used herein, the phrase “internal only pad” is used in its broadest sense to mean any I/O on a wafer that is not connected to an I/O on a packaged chip. In one embodiment, when the internal only pad is tied high by connection to ATE 103, test capability of circuit under test 105 is accessible. Prior to chip packaging of circuit under test 105, the internal only pad is tied low rendering test capability of circuit under test 105 is inaccessible. Based upon the disclosure provided herein, one of ordinary skill in the art will recognize other assertion levels applied to the internal only pad that may be used to render test capability of circuit under test 105 either accessible or inaccessible. Additionally, elements of circuit under test 105 that may be rendered inaccessible by assertion of the internal only pad are removed from scan chains to further secure the elements from surreptitious access.

Turning to FIG. 1b, another view of circuit test system 100 is shown. As shown, circuit under test 105 includes a scan chain 115. Of note, while circuit under test 105 is shown with one scan chain, it will be understood that circuit under test 105 may include any number of scan chains. Scan chain 115 includes a number of cells 110. A scan shift control signal (not shown) is utilized to cause cells 110 of scan chain 115 to be configured as a shift register when a scan test is enabled. In the shift register, a scan input of cell 110a is connected to a scan input from ATE 103, a scan output of cell 110a is connected to a scan input of cell 110b, a scan output of cell 110b is connected to a scan input of cell 110c, a scan output of cell 110c is connected to a scan input of cell 110d, a scan output of cell 110d is connected to a scan input of cell 110e, and a scan output of cell 110e is provided as a scan output to ATE 103. It should be noted that where more than one scan chain is included, each such scan chain can have the same number of cells, or different scan chains may include different numbers of cells. For example, the lengths of at least a subset of the scan chains within the integrated circuit may be balanced so that the same amount of time is needed to shift a desired set of scan test patterns into those scan chains.

The scan shift control signal may be implemented as, for example, a scan enable signal, such that cells 110 of scan chain 115 operate as a shift register accepting scan data when the scan enable is asserted at one logic level, and cells 110 of scan chain 115 operate as functional cells when the scan enable is asserted at another logic level. As circuit under test 105 may include more than one scan chain, a single scan shift control signal may be used to enable operation of all scan chains, or there may be individual scan enables associated with subsets of the scan chains. When scan chain 115 is configured to form a serial shift register for shifting in and shifting out scan test data associated with one or more test patterns to be applied by ATE 103, the scan test circuitry of circuit under test 105 may be said to be in a scan shift phase of a scan test mode of operation. It should be appreciated, however, that a wide variety of other types of scan shift control signals and sets of integrated circuit operating modes and phases may be used in other embodiments. These embodiments therefore do not require the use of any particular definition of operating modes and phases.

Scan chain 115 may be associated with multiple distinct clock domains, or a single clock domain. It will be assumed in some embodiments that scan chain 115 is a multiple clock domain scan chain, that is, a scan chain comprising sub-chains associated with respective distinct clock domains. Such sub-chains of a multiple clock domain scan chain may be separated from one another by lockup latches. Also, one or more of the sub-chains may be selectively bypassed using clock domain bypass circuitry so as to not be part of the serial shift register formed by the scan chain in the scan shift phase. For example, such clock domain bypass circuitry may be configured to bypass one or more of the sub-chains that are determined to be inactive for a particular test pattern, and the clock domain bypass circuitry may bypass different ones of the sub-chains for different test patterns. Additional details regarding clock domain bypass circuitry that may be utilized in embodiments of the invention may be found in U.S. Pat. Pub. No. 2013/0103994, filed Oct. 25, 2011 and entitled “Dynamic Clock Domain Bypass for Scan Chains”. The entirety of the aforementioned reference is incorporated herein by reference for all purposes.

Depending upon the particular embodiment, the scan shift control signal can be asserted either directly by one of external pads 145, or may be programmed to assert at a selected assertion level based upon a command received via one or more of external pads 145. As used herein, the phrase “external pad” is used in its broadest sense to mean any I/O on a wafer that is both accessible on the wafer before the wafer is encapsulated in a chip package, and also accessible via an I/O on a chip package after the wafer is encapsulated in the chip package. As an example, the scan shift control signal may be connected directly to one of external pads 145 in which case the assertion level applied to the particular external I/O pad directly controls the assertion level of the scan shift control signal. As another example, scan shift control signal may be controlled based upon a command received via one or more of external pads 145. Once the appropriate command is detected, the scan shift control is asserted at the selected logic level. In either case, because assertion of the scan shift control signal is controlled via external pads 145, switching circuit under test 105 between a scan mode (i.e., a mode in which cells 110 of scan chain 115 operate as a shift register) and a functional mode (i.e., a mode in which cells 110 operates as part of non-test functionality) is possible both before and after the wafer upon which circuit under test 105 is implemented is encapsulated in a chip package.

Circuit under test 105 includes blocks of combinational logic 125, 135. As used herein, the phrase “combinational logic” is used in its broadest sense to mean any arrangements of logic circuitry. Combinational logic 125, 135 each includes a variety of logic circuitry implementing functionality of a particular electronic device. As just some examples, such electronic devices may include, but are not limited to, a read channel and additional cores of a system-on-chip (SOC) integrated circuit in a hard disk drive (HDD) controller application designed for reading and writing data from one or more magnetic storage disks of an HDD. Based upon the disclosure provided herein, one of ordinary skill in the art will recognize a variety of electronic devices for which combinational logic 125, 135 implements the functionality thereof. Such combinational logic blocks 125, 135 are verified during various testing, including scan testing, under the control of ATE 103.

Combinational logic 125 logically couples one or more of cells 110 to one or more primary inputs 120. The coupling of primary inputs 120 to combinational logic 125 is shown using partially dashed lines indicating the possibility of one or more scan chains and combinational logic blocks intervening between primary inputs 120 and combinational logic 125. Similarly, combinational logic 135 logically couples one or more of cells 110 to one or more primary outputs 130. The coupling of combinational logic 135 primary outputs 130 is shown using partially dashed lines indicating the possibility of one or more scan chains and combinational logic blocks intervening between combinational logic 135 and primary outputs 130. Test control circuitry 150 may be implemented as part of ATE 103 in which case ATE 103 directly manipulates signals applied to external pads 145 and internal only pad 145 (prior to packaging the wafer on which circuit under test is implemented).

In operation, one or more of cells 110 are identified as secured memories. As used herein, the phrase “secured memory” is used in its broadest sense to mean any storage cell that is, after chip packaging, rendered inaccessible during at least a subset of test modes implemented as part of a particular integrated circuit. Designation as a secured memory is applied to a cell that is expected to include information sufficiently sensitive to desire additional security from surreptitious access. As an example, the cells may store sensitive user information during functional operation of circuit under test 105. To avoid the potential of a hacker gaining access to the information maintained by the identified cell(s) by placing circuit under test 105 in a test mode after deployment of a chip in which circuit under test 105 is implemented, the identified cell(s) are selectively removed from a part of the self test. In particular, testing of the identified cell(s) is limited to wafer testing prior to packaging. To do this, testing of the identified cell(s) is enabled by tying internal only pad 140 at a defined assertion level during wafer testing. Conversely, before packaging of circuit under test 105 is completed, internal only pad 140 is tied a the opposite assertion level such that test mode access to the identified cell(s) is disabled.

Each of the identified cell(s) is disconnected from a scan chain in which it would otherwise be included. Thus, as an example, assume cell 110b is identified as a secured memory, the scan output of cell 110a is connected to the scan input of cell 110b, and the scan output of cell 110b is disconnected. In this way a cell can be removed from the scan chain without destroying the operation of the scan chain. Further, a test access circuit (not shown) combines the output of the identified cell with the signal from internal only pad 140 such that the output of the identified cell is masked during operation of a test mode after packaging of the wafer upon which circuit under test is implemented. Conversely, the test access circuit combines the output of the identified cell with the signal from internal only pad 140 such that the output of the identified cell is unmasked when internal only pad is asserted at an enable logic level during operation of a test mode prior to packaging of the wafer upon which circuit under test is implemented. As such, access to the identified cell(s) during a test mode is possible prior to packaging, and not possible after packaging.

Turning to FIG. 1c, a cell 160 is shown that is not identified as a secured memory as described above in relation to FIG. 1b. As shown, cell 160 includes a memory cell 170. As used herein, the phrase “memory cell” is used in its broadest sense to mean any circuit structure capable of maintaining information. Memory cell 170 includes a scan input 175 that is received from a prior element in a scan chain, and a scan output 171 that is provided to a subsequent element in the scan chain. Thus, for example, where cell 160 represents cell 110b of FIG. 1b, scan input 175 is connected to the scan output of cell 110a and scan output 171 is connected to the scan input of cell 110c. Memory cell 170 further includes a memory input 177 from up stream combinational logic (i.e., from combinational logic 125 of FIG. 1b) and a memory output 173 that is provided to both a functional flip flop 172 and a self test flip flop 174. Of note, when cell 160 is placed in a scan test mode, memory cell 170 is incorporated within a scan chain shift register passing the information at scan input 175 to scan output 171. Additionally, in a test mode memory output 173 is available to self test flip flop 174.

Turning to FIG. 1d, a cell 180 is shown that is identified as a secured memory as described above in relation to FIG. 1b. As shown, cell 180 includes a memory cell 190. Memory cell 190 includes a scan input 195 that is received from a prior element in a scan chain, and is connect to a subsequent element in the scan chain. Memory cell 190 also includes a scan output 191 that is disconnected. Thus, for example, where cell 180 represents cell 110b of FIG. 1b, scan input 195 is connected to the scan output of cell 110a and to the scan input of cell 110c, and scan output 191 is disconnected. Memory cell 190 further includes a memory input 196 from up stream combinational logic (i.e., from combinational logic 125 of FIG. 1b) and a memory output 193. A gated output 199 is provided to both a functional flip flop 192 and a self test flip flop 194.

A test access circuit 197 (Outlined in dashed lines) combines memory output 193 with an internal pad signal 183 (i.e., the signal from internal only pad 140) such that memory output 193 is masked during operation of a test mode after packaging of the wafer upon which circuit under test is implemented. After packaging, internal pad signal 183 is tied to a logic level that causes gated output 199 to assert at a fixed logic level regardless of memory output 193. Prior to packaging, internal pad signal 183 may be asserted such that a gated output 199 follows memory output 193 when a test mode is selected based upon data from one or more external pads. Thus, test access circuit 197 combines memory output 193 with internal pad signal 183 such that memory output 193 is unmasked when internal pad signal 183 is asserted at an enable logic level during operation of a test mode prior to packaging of the wafer upon which circuit under test is implemented. As such, access to cell 180 during a test mode is possible prior to packaging, and not possible after packaging.

Test access circuit 197 includes an OR-gate 186 that logically ORs one or more test enable signals controlled from external pads 145. If any of the test enable signals is asserted high, a test select output 187 is asserted high. Only where all of the test enable signals are not asserted high is test select output 187 de-asserted. Internal pad signal 183 and test select output 187 are provided to a NAND gate 184. When internal pad signal 183 is tied to a logic one, test gate signal 185 follows test output 187. In particular, where internal only pad 140 is tied high (i.e., the condition when the wafer is packaged) causing internal pad signal 183 to be asserted at a logic one and a test is enabled via external pads 145 causing test select output 187 to be asserted as a logic one, test gate signal 185 is asserted as a logic zero. Memory output 193 and test gate signal 185 are provided to an AND gate 182 the output of which is gated output 199. Thus, where a test is enabled after the wafer is packaged (i.e., internal only pad 140 is tied high), memory output 193 is not visible in gated output 199. As such, cell 180 is effectively disabled when a test is enabled after packaging. Alternatively, where internal only pad 140 is tied high (i.e., the condition when the wafer is packaged) causing internal pad signal 183 to be asserted at a logic one and a test is not enabled via external pads 145 causing test select output 187 to be asserted as a logic zero, test gate signal 185 is asserted as a logic one. In this condition, gated output 199 follows memory output 193. Thus, memory output 193 is enabled during functional operation after the wafer is packaged (i.e., internal only pad 140 is tied high). As such, even though the test modes of cell 180 are disabled, the functional modes of cell 180 remain operational after packaging. Alternatively, where prior to packaging internal only pad 140 is tied low, test gate signal 185 is asserted as a one and gated output 199 follows memory output 193. As such, memory output 193 is visible in both test modes and functional modes prior to wafer packaging. It should be noted that OR gate 186 and NAND gate 184 may be share across multiple cells while AND gate 182 is replicated for each cell.

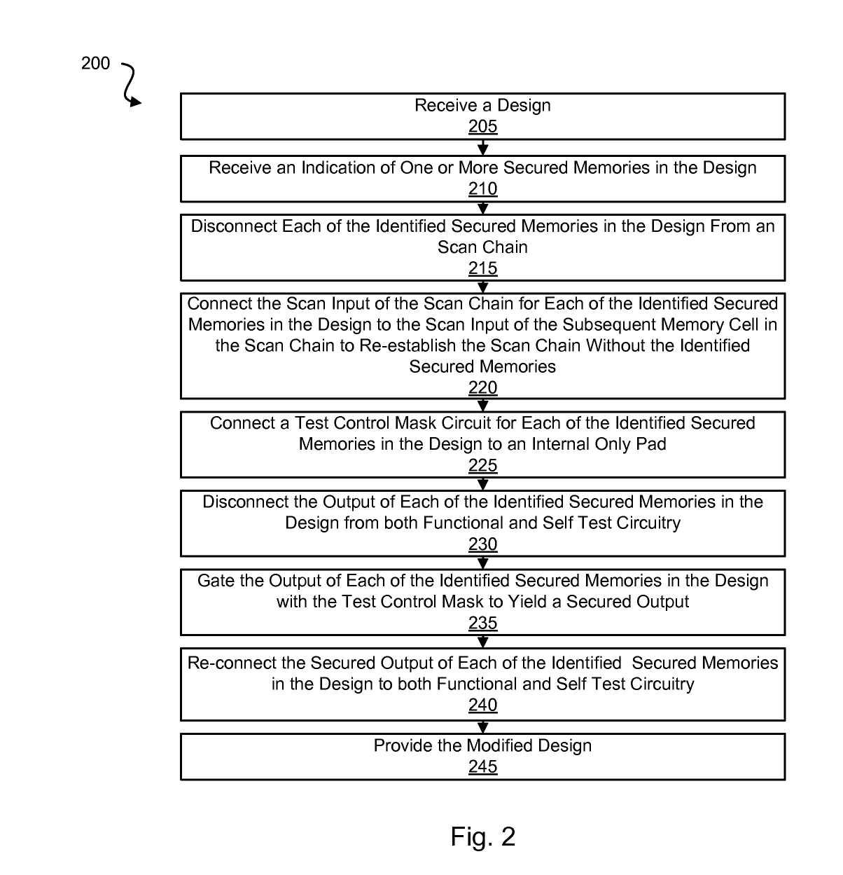

Turning to FIG. 2, a flow diagram 200 shows a method in accordance with one or more embodiments of the present invention for securing select portions of a circuit. Following flow diagram 200, a design is received (block 205). The design includes a number of memory cells and a variety of combinational logic implemented to perform the desired functions of a semiconductor device. The memory cells are arranged in one or more scan chains with intervening blocks of combinational logic. In some cases, the design may include elements arranged similar to that of circuit under test 105 discussed above in relation to FIG. 1b. Based upon the disclosure provided herein, one of ordinary skill in the art will recognize a variety of designs that may be received in relation to different embodiments of the present invention.

An indication of one or more secured memories in the received design is received (block 210). This may be received, for example, via a user interface that allows a user to designate a subset of the memory cells in the received design as secured memories. Alternatively, the indication of the secured memories may be automatically generated based upon simulation data from the received design. The secured memories may include, but are not limited to, memory cells that store sensitive data during functional operation of the received memory, and where it is desired to avoid surreptitious access to the sensitive data by a hacker through one or more test mechanisms available in the received memory.

Each of the identified secured memories is disconnected from a scan chain in which it operates (block 215). This includes, for example, disconnecting a scan output of a respective secured memory from a scan input of a downstream memory cell. Upon disconnection, the scan input/output of the secured memory is similar to that discussed above in relation to cell 180 of FIG. 1d. The scan input of the scan chain for each of the identified secured memories in the received design is connected to the scan input of the subsequent memory cell in the scan chain to re-establish the scan chain without the identified secured memories (block 220).

A test control mask circuit is connected for each of the identified secured memories in the received design to an internal only pad (block 225). As one example, this may include connecting a circuit similar to test access circuit 197 of FIG. 1d to an output of the identified secured memory. The output of each of the identified secured memories in the received design is disconnected from both the function and self test circuitry of the received design (block 230). Using cell 180 of FIG. 1d as an example, memory output 193 is disconnected from functional flip flop 192 and self test flip flop 194. The output of each of the identified secured memories is gated with a test control mask from the test control mask circuit with the result being a secured output (block 235). Using cell 180 of FIG. 1d again as an example, memory output 193 is gated with test gate signal 185 (i.e., the test control mask) to yield gated output 199 (i.e., the secured output). The secured output of each of the identified secured memories in the received design is connected to the corresponding functional and self test circuitry (block 240). Again, using cell 180 of FIG. 1d as an example, this includes connecting gated output (i.e., the secured output) to functional flip flop 192 and self test flip flop 194. By connecting to the internal only pad, access to the information maintained in the identified secured memory is not accessible when the internal only pad is tied to a disable assertion level. This tying may be done upon packaging a wafer upon which the circuit is implemented. Alternatively, when the wafer is still accessible prior to packaging, the internal only pad is tied to an assertion level that allows access to the test functionality. The functional operability of the circuit is accessible regardless of the assertion level of the internal only pad. The modified design is then provided as an output for implementation (block 245).

Turning to FIG. 3, a circuit design system 390 is shown that integrates circuit security in accordance with particular embodiments of the present invention. Circuit design system 390 includes a processing station 391 that is communicably coupled to a design database 396. In one particular embodiment of the present invention, processing station 391 is a personal computer including a display device, a processor, and/or one or more I/O devices. Based upon the disclosure provided herein, one of ordinary skill in the art will recognize a variety of systems that may be used as processing station 391 including highly tailored application specific control systems. A storage medium 394 is communicably coupled to processing station 391 and maintains instructions governing the operation to control the modification of a design accessed from design database 396. In particular, storage medium 394 maintains instructions to perform secure design modification control.

In operation, processing station 391 accesses a design from design database 396. The design includes a number of memory cells and a variety of combinational logic implemented to perform the desired functions of a semiconductor device. The memory cells are arranged in one or more scan chains with intervening blocks of combinational logic. In some cases, the design may include elements arranged similar to that of circuit under test 105 discussed above in relation to FIG. 1b. Based upon the disclosure provided herein, one of ordinary skill in the art will recognize a variety of designs that may be received in relation to different embodiments of the present invention.

A user provides an indication of one or more secured memories in the received design via I/O of processing station 391. The secured memories may include, but are not limited to, memory cells that store sensitive data during functional operation of the received memory, and where it is desired to avoid surreptitious access to the sensitive data by a hacker through one or more test mechanisms available in the received memory.

Processing station 391 executes instructions accessed from storage medium 394 that causes processing station 391 to disconnect each of the identified secured memories from a scan chain in which it operates. This includes, for example, disconnecting a scan output of a respective secured memory from a scan input of a downstream memory cell. Upon disconnection, the scan input/output of the secured memory is similar to that discussed above in relation to cell 180 of FIG. 1d. Processing station 391 further executes instructions accessed from storage medium 394 that causes processing station 391 to connect the scan input of the scan chain for each of the identified secured memories in the received design to the scan input of the subsequent memory cell in the scan chain to re-establish the scan chain without the identified secured memories.

Processing station 391 further executes instructions accessed from storage medium 394 that causes processing station 391 to connect a test control mask circuit for each of the identified secured memories in the received design to an internal only pad. As one example, this may include connecting a circuit similar to test access circuit 197 of FIG. 1d to an output of the identified secured memory. Processing station 391 further executes instructions accessed from storage medium 394 that causes processing station 391 to disconnect the output from each of the secured memories from both the function and self test circuitry of the received design. Using cell 180 of FIG. 1d as an example, memory output 193 is disconnected from functional flip flop 192 and self test flip flop 194.

Processing station 391 further executes instructions accessed from storage medium 394 that causes processing station 391 to gate the output of each of the identified secured with a test control mask from the test control mask circuit with the result being a secured output. Using cell 180 of FIG. 1d again as an example, memory output 193 is gated with test gate signal 185 (i.e., the test control mask) to yield gated output 199 (i.e., the secured output). Processing station 391 further executes instructions accessed from storage medium 394 that causes processing station 391 to connect the secured output of each of the identified secured memories to the corresponding functional and self test circuitry. Again, using cell 180 of FIG. 1d as an example, this includes connecting gated output (i.e., the secured output) to functional flip flop 192 and self test flip flop 194. By connecting to the internal only pad, access to the information maintained in the identified secured memory is not accessible when the internal only pad is tied to a disable assertion level. This tying may be done upon packaging a wafer upon which the circuit is implemented. Alternatively, when the wafer is still accessible prior to packaging, the internal only pad is tied to an assertion level that allows access to the test functionality. The functional operability of the circuit is accessible regardless of the assertion level of the internal only pad.

It should be noted that the various blocks discussed in the above application may be implemented in integrated circuits along with other functionality. Such integrated circuits may include all of the functions of a given block, system or circuit, or a subset of the block, system or circuit. Further, elements of the blocks, systems or circuits may be implemented across multiple integrated circuits. Such integrated circuits may be any type of integrated circuit known in the art including, but are not limited to, a monolithic integrated circuit, a flip chip integrated circuit, a multichip module integrated circuit, and/or a mixed signal integrated circuit. It should also be noted that various functions of the blocks, systems or circuits discussed herein may be implemented in either software or firmware.

In conclusion, the invention provides novel systems, devices, methods and arrangements for circuits, circuit design, and circuit testing. While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A semiconductor device, the device comprising:
a wafer upon which an overall circuit is implemented, wherein the overall circuit includes: a first cell, a second cell, an internal only pad, an external pad, a gate circuit, and a test circuit;
wherein the test circuit is coupled to an output of the second cell and an output of the gate circuit;
wherein the overall circuit is selectably operable in a test mode or a functional mode based upon data received via the external pad;
wherein a first input of the gate circuit is coupled to the internal only pad and a second input of the gate circuit is coupled to an output of the first cell, and wherein the gate circuit is configured such that:
the output of the gate circuit follows the output of the first cell when the internal only pad is asserted at a first level and the test mode of the overall circuit is selected; and
the output of the gate circuit is fixed regardless of the output of the first cell when the internal only pad is asserted at a second level and the test mode of the overall circuit is selected.

2. The device of claim 1, wherein the output of the gate circuit is configured to follow the output of the first cell when the functional mode of the overall circuit is selected.

3. The device of claim 1, the device further comprising:
a test system electrically coupled to the wafer, wherein the test system is operable to assert the internal only pad at the first level.

4. The device of claim 3, wherein the test system is further operable to assert the external pad such that the test mode of the overall circuit is selected.

5. The device of claim 1, the device further comprising:
a chip package encapsulating the wafer and including a plurality of pins, wherein the external pad is bonded to one of the plurality of pins, and wherein the internal only pad is inaccessible via the plurality of pins.

6. The device of claim 1, the device further comprising:
a chip package encapsulating the wafer, wherein the external pad is bonded to a contact on the chip package such that the external pad is electrically accessible external to the chip package, and wherein the internal only pad is tied to the second level internal to the chip package.

7. The device of claim 6, wherein the internal only pad is not controllable external to the chip package beyond a power source applied to the chip package.

8. The device of claim 1, wherein the overall circuit includes at least one scan chain, wherein the second cell is included in the scan chain, and wherein the first cell is not incorporated in any of the at least one scan chain.

9. The device of claim 1, wherein the device is deployed as part of a consumer electronic device.

10. The device of claim 9, wherein the consumer electronic device is selected from a group consisting of: a hard disk drive, and a communication device.

11. The device of claim 1, wherein the gate circuit comprises:
a NAND gate having a first input coupled to the internal only pad and a second input coupled to a test select output associated with the external pad, and providing a gate signal; and
an AND gate having a first input coupled to the gate signal and a second input coupled to the output of the first cell, and providing the output of the gate circuit.

12. A method for deploying a semiconductor device, the method comprising:
providing the semiconductor device, the semiconductor device comprising:
a wafer upon which an overall circuit is implemented, wherein the overall circuit includes: a first cell, a second cell, an internal only pad, an external pad, a gate circuit, and a test circuit;
wherein the test circuit is coupled to an output of the second cell and an output of the gate circuit;
wherein the overall circuit is selectably operable in a test mode or a functional mode based upon data received via the external pad;
wherein a first input of the gate circuit is coupled to the internal only pad and a second input of the gate circuit is coupled to an output of the first cell, and wherein the gate circuit is configured such that:
the output of the gate circuit follows the output of the first cell when the internal only pad is asserted at a first level and the test mode of the overall circuit is selected; and
the output of the gate circuit is fixed regardless of the output of the first cell when the internal only pad is asserted at a second level and the test mode of the overall circuit is selected.

13. The method of claim 12, the method further comprising:
electrically connecting the wafer to a test system;
tying the internal only pad at the first level;
asserting the external pad by the test system to engage a test mode of the overall circuit; and
verifying the wafer using the test system.

14. The method of claim 12, the method further comprising:
tying the internal only pad at the second level; and
encapsulating the wafer in a chip package such that the internal only pad is inaccessible external to the chip package.

15. The method of claim 14, wherein encapsulating the wafer in the chip package includes:
bonding an external contact of the chip package to the external pad; and
bonding the internal only pad to an internal power rail of the chip package.

16. The method of claim 15, wherein the internal only pad is not controllable external to the chip package beyond a power source applied to the chip package.

17. The method of claim 12, wherein the gate circuit comprises:
a NAND gate having a first input coupled to the internal only pad and a second input coupled to a test select output associated with the external pad, and providing a gate signal; and
an AND gate having a first input coupled to the gate signal and a second input coupled to the output of the first cell, and providing the output of the gate circuit.

18. The method of claim 12, wherein the overall circuit includes at least one scan chain, wherein the second cell is included in the scan chain, and wherein the first cell is not incorporated in any of the at least one scan chain.

19. A circuit design tool, the design tool comprising:
a processor operable of receiving a representation of an overall circuit, wherein the overall circuit includes a first cell, a second cell, a third cell, an internal only pad, an external pad, a gate circuit, and a test circuit; and wherein the processor is communicably coupled to a computer readable medium including instructions executable by the processor to:
receive an identification of the cell as a secured memory;
disconnect the secured memory from a scan chain in the overall circuit;
connect a scan output from the second cell upstream from the secured memory in the scan chain to a scan input of the third cell downstream from the secured memory in the scan chain;
connect the gate circuit to the secured memory such that a first input of the gate circuit is coupled to the internal only pad and a second input of the gate circuit is coupled to an output of the secured memory, and wherein the gate circuit is configured such that:
the output of the gate circuit follows the output of the secured memory when the internal only pad is asserted at a first level and the test mode of the overall circuit is selected; and
the output of the gate circuit is fixed regardless of the output of the secured memory when the internal only pad is asserted at a second level and the test mode of the overall circuit is selected.

20. The circuit design tool of claim 1, wherein the gate circuit comprises:
a NAND gate having a first input coupled to the internal only pad and a second input coupled to a test select output associated with the external pad, and providing a gate signal; and
an AND gate having a first input coupled to the gate signal and a second input coupled to the output of the first cell, and providing the output of the gate circuit.
